(19) United States
(12) Patent Application Publication
(10) Pub. No.: US 2016/0141225 A1
(43) Pub. Date: May 19, 2016

(54) LATENT HEAT STORAGE DEVICES

(71) Applicant: SGL CARBON SE, Meitingen (DE)

(72) Inventor: Mike Roemmler, Los Angeles, CA (US)

(21) Appl. No.: 14/543,764

(22) Filed: Nov. 17, 2014

(51) Int. Cl. H01L 23/427; H01L 23/373; H01L 21/56; C09K 5/06

(52) U.S. Cl. CPC H01L 23/4275; C09K 5/063; H01L 23/373; H01L 21/56

(57) ABSTRACT

An apparatus including a composite structure including an expanded graphite matrix infiltrated with a phase change material having dimensions configured for association with an electronic device, the composite structure including a thermal conductivity greater than 5 Watts per meter Kelvin (W/mK). An apparatus including an integrated circuit package; a planar pad including an expanded graphite matrix; and a heat sink, wherein the pad is disposed between the integrated circuit package and the heat sink. A method including placing a structure including an expanded graphite matrix on an integrated circuit package; and coupling a passive heat exchanger to the structure.

### FIELD

Latent heat storage devices.

### BACKGROUND

Phase change materials (PCM) are capable of storing heat energy in the form of latent heat. Such materials undergo a phase transition when heat is supplied or removed, e.g., a transition from the solid to the liquid phase (melting) or from the liquid to the solid phase (solidification) or a transition between a low-temperature and high-temperature modification or a hydrated and a de-hydrated modification or between different liquid modifications. If heat is supplied to or removed from a phase change material, on reaching the phase transition point, the temperature remains constant until the material is completely transformed. The heat supplied or released during the phase transition, which causes no temperature change in the material, is known as latent heat.

Unfortunately, the heat conductivity of most phase change materials is relatively low. As a consequence, the charging and discharging of a latent heat storage device is a relatively slow process. Granted European Patent No. EP 0914399 B1 discloses a composite for storage of latent heat and the process of manufacturing such a composite. The composite includes an inert graphite matrix with a bulk density of more than 75 grams per liter (g/l) that is infiltrated under vacuum with a solid/liquid phase change material (PCM).

A graphite matrix is made by compressing expanded graphite to a density between 75 and 1500 grams/liter (g/l), preferably between 75 g/l and 500 g/l. The storage composite is obtained by vacuum infiltration of the PCM into the preformed matrix. Prior to the infiltration, the matrix is evacuated to a pressure of 10 mbar or below, and the PCM is heated to a temperature which is preferably between 10 and 40 Kelvin (K) above the melting point, but at most up to the evaporation temperature of the PCM. As a result of a valve leading to the PCM vessel being opened, the molten PCM, which is present in excess, flows into the graphite matrix. Then, the storage composite is preferably cooled to below room temperature, in order to reduce the escape of PCM gases until the storage container is closed.

An alternative process for vacuum infiltration of a matrix made by compression of expanded graphite was disclosed in published U.S. Patent Publication No. 2002/060063. The process described includes the steps of partially or completely immersing the matrix, which is fixed inside an infiltration vessel, under atmospheric pressure in a molten phase change material, and evacuation of the infiltration vessel until the desired degree of loading of the matrix with the PCM has been achieved. The vacuum infiltration process can be continued until the residual porosity of the composite is less than one percent by volume. This residual porosity can be reached after an infiltration period of up to approximately five hours, preferably of approximately up to three hours. The graphite matrix expediently has a density of about 75 to about 1500 g/l, preferably about 75 to about 500 g/l, particularly preferably approximately of about 200 g/l.

Another type of latent heat storage composite is disclosed in U.S. Patent Publication No. 2005/0258394. Within this composite, flakes of natural graphite and/or synthetic graphite having a high anisotropy of thermal conductivity and a high aspect ratio form the auxiliary heat conducting component. A composite is obtained, for example, by infiltration of the liquid phase change material into a bed containing graphite flakes as a bulk good. Infiltration can be supported by vacuum or pressure, but this is not necessary.

### BRIEF DESCRIPTION OF THE DRAWINGS

FIG. 1 is a cross-sectional side view illustrating a digital circuit assembly using a graphite matrix that may be infiltrated with a phase change material.

FIG. 2 shows an embodiment of a digital circuit assembly that representatively is operable for use in a computing device with a passive heat exchanger laterally adjacent a heat source.

### DETAILED DESCRIPTION

Processes for the production of expanded graphite are known from, for example, sources such as U.S. Pat. No. 3,404,061. The starting material is flaky natural graphite or synthetic graphite. The graphite flakes of the starting material are treated with a solution of an intercalating agent, e.g., with a mixture of concentrated sulfuric acid and nitric acid, with fuming nitric acid or with a mixture of hydrogen peroxide and concentrated sulfuric acid, resulting in the formation of a graphite salt or a similar graphite intercalation compound. Further intercalation agents are known in the art. U.S. Pat. No. 6,645,456 discloses an intercalation mixture formed of at least one strong concentrated acid selected from the group consisting of sulfuric acid and nitric acid, an oxidizing agent selected from the group consisting of concentrated nitric acid, hydrogen peroxide and peroxo sulfuric acid for oxidizing the graphite, and a thermal polyphosphoric acid.

The graphite-intercalation compounds or graphite salts, for example, graphite hydrogen sulfate or graphite nitrate, are heated in a shock-like manner. Conventionally, the intercalated graphite is expanded by a factor of between 100 and 300. The expansion reduces the density from about 600 grams per liter (g/l) to 700 g/l of the intercalation compound to about 2 g/l to 7 g/l of the expanded graphite. The expanded graphite material includes vermiform or concertina-shaped aggregates. If the expanded graphite is compacted under the directional action of pressure, the layer planes of graphite preferably align perpendicularly to the direction of action of pressure, with the individual aggregates hooking up with each other. As a result, planar structures, for example, sheets, webs or plates, of graphite matrix can be produced that are self-supporting without the addition of any binder. In this way, planar structures with a thickness between 0.1 millimeters (mm) and 3 mm and an area weight between 100 grams per square centimeter (g/cm²) and 3,000 g/cm² can be made. The thermal conductivity in a direction parallel to the plane of the foil is between 70 watts per meter Kelvin (W/mK) and 500 W/mK while the thermal conductivity perpendicular to the plane of the foil is only between 3 W/mK and 6 W/mK. The thermal anisotropy tends to be more pronounced the higher the density of the foil, because stronger compression leads to a more pronounced alignment of the basal planes.

In one embodiment, a composite structure is described that includes a planar structure, such as a sheet, web, pad or plate, of graphite matrix, a graphite matrix, that may or may not be infiltrated or impregnated with a phase change material. Suitable phase change materials are, for example, paraffins, sugar alcohols, thermoplastic polymers, water, aqueous solutions of salts, salt hydrates, mixtures of salt hydrates, salts (particularly chlorides and nitrates) and eutectic blends of salts and alkali metal hydroxides. In one embodiment, a suitable phase change material has a latent heat capacity of 100 Joules per gram (J/g) or more. Typical salt hydrates utilitzable as phase change materials are, e.g., calcium chloride hexahydrate and sodium acetate trihydrate. Representatives of sugar alcohols are e.g., pentaerythritol, trimethylolethane, erythritol, mannitol, neopentyl glycol and their mixtures. In one embodiment, the phase change material is a fatty acid derivative or a derivative of a blend of fatty acids such as coconut oil, palm oil and soybean oil. Examples include Pure Temp PT37, PT48 and PT56, commercially available from Entropy Solutions, Inc. of Minneapolis, Minn. and RT42, commercially available from Rubitherm, GmbH. In another embodiment, the phase change material is wax such as beeswax or other paraffin.

In one embodiment, a composite structure has a graphite matrix density of 0.075 grams per cubic centimeter (g/cm³) to 0.5 g/cm³. In one embodiment, a composite structure has a latent heat capacity of 100 J/g to 185 J/g (e.g., greater than 100 J/g) and a thermal conductivity greater than 5 watts per meter Kelvin (W/mK), such as on the order of up to 100 W/mK. A property of a composite structure of a graphite matrix infiltrated or impregnated with a phase change material is based on a level (e.g., amount) of infiltration. In one embodiment, a composite structure will have an amount of phase change material between 70 and 95 percent by volume. In one embodiment, a composite structure will have a graphite matrix density between 0.2 g/cm³ to 0.7 g/cm³ and, in another embodiment, between 0.25 g/cm³ and 0.55 g/cm³. A composite structure with a graphite matrix density of 0.55 g/m³ will have a smaller amount of phase change material in the structure (e.g., about 75 percent by volume phase change material) than a composite structure with a graphite matrix density of 0.25 g/cm³ (e.g., about 88 percent by volume phase change material). Accordingly, a composite structure having a graphite matrix density of 0.55 g/cm³ will be more thermally conductive than a composite structure having a graphite matrix density of 0.25 g/cm³. On the other hand, a latent heat capacity of the composite structure will be reversed, with a latent heat capacity of a composite structure having a graphite matrix density of 0.55 g/cm³ being 105 J/g and a latent heat capacity of a composite structure having a graphite matrix density of 0.25 g/cm³ being 155 J/g.

The phase change material may infiltrate the graphite matrix by vacuum infiltration such as described in U.S. Patent Publication No. 2002/0060063 (vacuum impregnation) using molten phase change material. A representative process generally includes evacuating an infiltration vessel containing graphite matrix sheets and phase change material in solid form. The vessel is then heated to a temperature above the melting point of the phase change material. The molten phase change material is absorbed by the porous graphite matrix resulting in a graphite/phase change material composite. Other infiltration processes may also be suitable.

In one embodiment, the graphite matrix described herein or a composite structure (graphite matrix impregnated with phase change material) may be employed in thermal management of an electronic device or devices. Representative examples of an electronic device is a chip, such as a microprocessor (e.g., central processing unit, graphics processor, digital signal processor etc.), system on a chip (SOC), memory chip, power handling semiconductor devices, optoelectronic devices (e.g., lasers, light emitting diodes), and assemblies and modules including devices such as packages (including multichip packages), printed circuit board and insulated gate bipolar transistor (IGBT) modules.

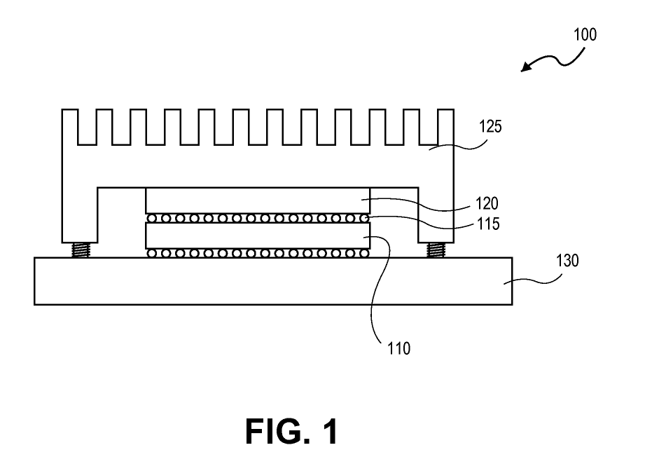

FIG. 1 is a cross-sectional side view illustrating a digital circuit assembly using a graphite matrix infiltrated that may be infiltrated with a phase change material. As illustrated, digital circuit assembly 100 includes integrated circuit (IC) package 110 housing, in one embodiment, a microprocessor chip. Such assembly representatively is operable for use in a computing device, such as a desktop station or a mobile computing device (e.g., laptop, tablet device, or smart phone). Additional uses include, but are not limited to, in server applications. Package 110 is connected to printed circuit board (PCB) 130 through, for example, solder connections. Printed circuit board 130 includes a number of integral signals lines for carrying signals to and from IC package 110. Package 110 is connected to printed circuit board 130 to provide signal communication between the signal lines of printed circuit board 130 and the chip associated with package 110. When operating, for example, a microprocessor chip generates heat due to power dissipation within its circuitry. In one embodiment, it is desirable to remove some of this heat to maintain an acceptable operating temperature for the chip. Accordingly, in the embodiment shown in FIG. 1, digital circuit assembly 100 includes a passive heat exchanger such as heat sink 125 to facilitate heat removal from the package 110. Assembly also includes pad 120 of a graphite matrix that may or may not be infiltrated with a phase change material disposed between the package 110 and heat sink 125. In one embodiment, pad 120 is a planar structure (e.g., rectangular) having dimensions (length and width dimensions) similar to a microprocessor chip disposed in package 110. In another embodiment, pad has length and width dimensions greater than length and width dimensions of a microprocessor chip (e.g., 5 percent to 20 percent greater). In one embodiment, pad has a representative thickness on the order of less than 100 microns (μm) such as 20 μm to 70 μm and, in another embodiment, 25 μm to 50 μm. Pad 120 can be electrically conductive and, therefore, in one embodiment, is encapsulated (surrounded) with a dielectric material such as, but not limited to, polyethylene terephthalate (PET) such as MYLAR®.

In one embodiment, pad 120 is in direct physical contact with package 110 (i.e., a surface of pad 120 directly contacts a surface of package 110). Pad 120 is therefore thermally connected to package 110. In one embodiment, pad 120 is also in direct physical contact with heat sink 125 (e.g., a surface on one side of pad 120 directly contacts an underside surface of heat sink 125 and a surface on an opposite side is in direct contact with a surface of package 110). In another embodiment, digital circuit assembly 100 includes thermal interface material (TIM) 115 disposed at one or both of the interface between package 110 and pad 120 and the interface of pad 120 and heat sink 125. A suitable TIM includes but is not limited to a polymer TIM as known in the art. A representative thickness of a TIM, if present, is on the order of 10 μm to 30 μm.

In digital circuit assembly 100 shown in FIG. 1, pad 120 of a composite of a graphite matrix infiltrated with a phase change material is utilized to reduce a thermal resistance of the interface, thus increasing heat flow away from the package 110. In operation, heat is generated in the package and is directed away from the package by pad 120. The heat then flows from pad 120 into heat sink 125 and is radiated into the surrounding environment by a plurality of fins on an opposite side of the heat sink (opposite a side adjacent pad 120).

In the embodiment described with reference to FIG. 1, the passive heat sink is placed directly on (over as viewed) a heat source of package 110. In another embodiment, a heat dissipation component including a composite of a graphite matrix infiltrated with a phase change material or another component may be used to direct heat, laterally away from to a heat source (e.g., circuit device or package).

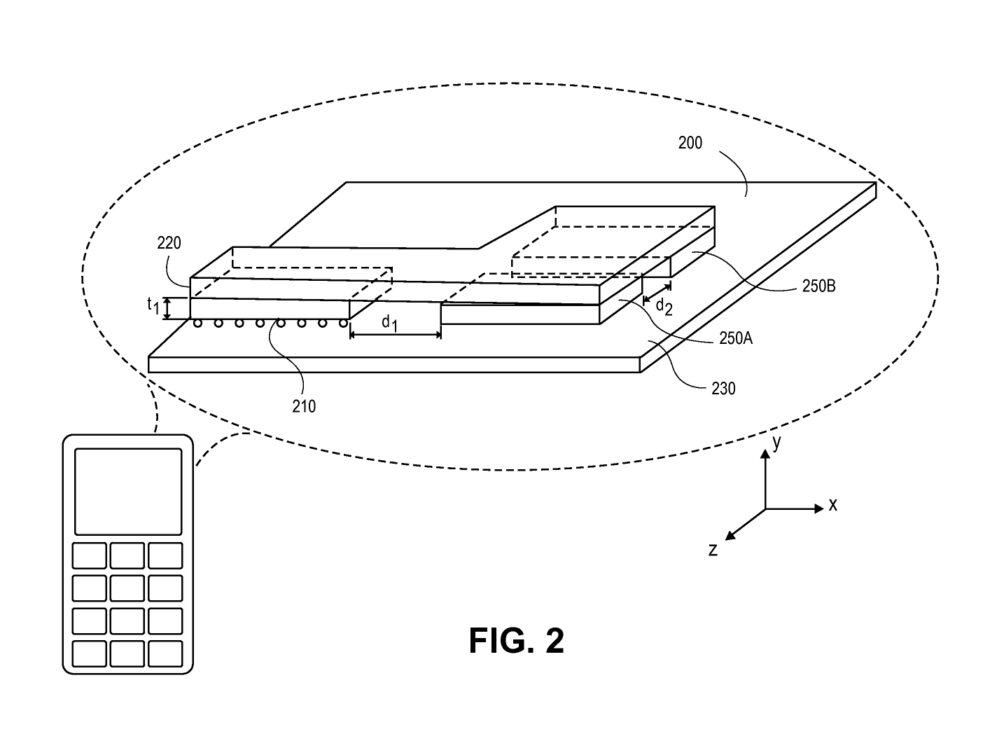

FIG. 2 shows an embodiment of a digital circuit assembly that representatively is operable for use in a computing device (e.g., server, desktop computer, mobile computer, tablet, phone). Assembly is illustrated as a component of a mobile phone. Assembly 200 includes integrated circuit package 210 that includes, in one embodiment, a microprocessor chip. In another embodiment, integrated circuit package 210 is a multichip package that includes more than one chip (e.g., microprocessor and one or more companion chips (e.g., memory, secondary processor)). Package 210 is connected to printed circuit board 230 through, for example, solder connections. In operation, package 210 is a heat source in the sense that it generates heat due, for example, to power dissipation within circuitry of the chip or chips in the package.

To remove heat generated by package 210, assembly 200 in FIG. 2 utilizes heat dissipation device 220 that is in the form of a planar pad having a thickness on the order of less than 100 μm. In one embodiment, heat dissipation device 220 is graphite matrix made from expanded natural graphite flake such as SIGRAFLEX® commercially available from SGL Group or from graphitized polyimide foil such as KAPTON® commercially available from E.I. duPont de Nemours and Company. In another embodiment, heat dissipation device 220 is a graphite matrix that may or may not be infiltrated or impregnated with a phase change material. For a composite material of a graphite matrix and a phase change material, suitable phase change materials for such a composite include those referenced above. Since heat dissipation device 220 is operable to dissipate heat from an area associated with a heat source (e.g., a chip or chips) to an area laterally away from the heat source, in one embodiment, heat dissipation device 220 of a composite of a graphite matrix infiltrated with a phase change material is targeted to have a high thermal conductivity (e.g., a thermal conductivity on the order of 0.55 g/cm³). Heat dissipation device 220 can be electrically conductive. Accordingly, in one embodiment, pad 120 is encapsulated (surrounded) with a dielectric material such as MYLAR™.

Referring to FIG. 2, in one embodiment, heat dissipation device 220 has dimensions (length and width dimensions in an x- and z-direction, respectively) that, in one embodiment, are similar to length and width dimensions of package 210 or a chip or chips within package 210 (e.g., a portion on (over) package 210 is 10 percent larger to 10 percent smaller than the length and width dimensions of package 210 or a chip or chips within package 210). The length and width dimensions of heat dissipation device 220 also extend laterally away from package 210 such that heat dissipation device 220 overlies one or more blocks positioned on printed circuit board 230 laterally adjacent or near package 210. FIG. 2 shows assembly 200 including block 250A and block 250B, in a plane including package 210 with the blocks each spaced a distance, d₁, in an x-direction from package 210 on printed circuit board 230. In one embodiment, block 250A and block 250B are a composite such as described above of a graphite matrix infiltrated with a phase change material. In one embodiment, block 250A and block 250B each have a thickness, including any connection mechanism to printed circuit board 230, corresponding to a thickness, t₁, of package 210. Blocks 250A and 250B are, in one embodiment, of similar length and width dimensions and, in one embodiment, are aligned in a z-direction. Block 250A and block 250B representatively each have a volume of the order of 2.5 cubic centimeters (cm³) to 5 cm³ and are separated by a distance, d₂, to provide a volume therebetween of 2.5 cm³ to 5 cm³. As illustrated, heat dissipation device 220 is disposed on (over as viewed) block 250A and block 250B. In one embodiment, heat dissipation device 220 is connected to each block by an adhesive. In an embodiment where heat dissipation device 220 is a composite of a graphite matrix and a phase change material, block 250A and block 250B of a similar composite may be eliminated or block 250A and block 250B may each be a composite having a different thermal property than heat dissipation device 220. Representatively, heat dissipation device 220 may have a thermal conductivity of 0.55 g/cm³ and block 250A and block 250B each have a thermal conductivity of 0.25 g/cm³.

Representatively, heat dissipation device 220 functions to dissipate or transfer heat away from heat source 210 (e.g., a chip) laterally to block 250A and/or block 250B. Block 250A and block 250B are thermally connected to the heat source through heat dissipation device 220 and, in one embodiment, are each operable to absorb heat as a heat sink for at least a period of time, such as three minutes to five minutes. Three to five minutes is generally a sufficient amount of time for a portable computing device such as a smart phone to perform a function that might result in the chip or chips generating a significant amount of heat (e.g., a search function). Heat dissipation device 220 is positioned and operable to dissipate heat from the heat source to heat block 250A and heat block 250B.

### EXAMPLE 1

### Preparation of Phase Change Material (PCM) Impregnated Graphite Sheets (GPCM)

Expanded graphite sheets were cut into 12″×12″ sheets of different thickness (1 mm to 4 mm) and different density (0.25-0.5 g/cc).

A 12″×12″ metal sheet was placed on a bottom of a basket, and the graphite sheets were stacked one on top of the other on the metal sheet followed by another metal sheet on the top of the graphite sheets.

A PCM in solid form was placed on top of the stack of graphite sheets and the loaded basket was placed in a container (metal or plastic) to contain melted PCM. The container was then loaded into a vacuum oven capable of heating 107° C. or higher, with capacity of 4 cubic feet volume loading and vacuum controls. The over door was closed and a vacuum pump started. A vacuum was maintained at a pressure of 25 in (Hg). An oven temperature was set at a temperature of up to 20° C.-25° C. higher than a melting point of the PCM to be used. Representative oven temperatures include, for example, 65-70° C. for PT37; 70-75° C. for PT48 and PT56; and 60° C. for RT42. The temperature is selected such that the PCM will melt to a liquid state and penetrate the pores of the expanded graphite sheets.

The temperature and pressure was maintained on the graphite sheets for 5 hours. After 5 hours, the vacuum on the furnace was stopped and the temperature maintained until all the containers were removed.

Upon removal of a container from the furnace, the container was placed on a flat surface. The wire basket was held in such a manner to separate the graphite sheets from excess liquid PCM in the container. The graphite sheets infiltrated with PCM were allowed to solidify for a few minutes, then put on a tray and the tray with basket into the preheated oven (65° C. for PT37 sample). A 10 pound weight was placed on top of the metal plate to keep the sheets flat. The tray was kept in the oven for 2 hours to remove the excess PCM, then cooled to room temperature.

The PCM infiltrated graphite sheets were separated by hand. Porosity and density were calculated based on the weight before and after the impregnation (bulk density of graphite is 0.5 g/cm³ for sheet desirous of high thermal conductivity and 0.25 g/cm³ for sheets desirous of high latent heat capacity). Real density of graphite is assumed to be 2.25 g/cm³.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. An apparatus comprising:
a composite structure comprising an expanded graphite matrix infiltrated with a phase change material having dimensions configured for association with an electronic device, the composite structure comprising a thermal conductivity greater than 5 Watts per meter Kelvin (W/mK).

2. The apparatus of claim 1, wherein the electronic device comprises a packaged chip and the composite structure is in the form of a planar pad having length and width dimensions similar or larger to length and width dimensions of the packaged chip.

3. The apparatus of claim 1, wherein the composite structure has a graphite matrix density of 0.25 grams per cubic centimeter (g/cm³) to 0.55 g/cm³.

4. The apparatus of claim 1, wherein the composite structure has a latent heat capacity of 100 Joules/gram (J/g) to 300 J/g.

5. The apparatus of claim 1, wherein the phase change material is a fatty acid derivative.

6. An apparatus comprising:
an integrated circuit package; and
a heat dissipation device or a planar pad comprising an expanded graphite matrix and phase change material coupled to the integrated circuit package; and
a heat sink.

7. The apparatus of claim 6, wherein the pad is disposed between the integrated circuit package and the heat sink.

8. The apparatus of claim 7, wherein the pad has a graphite matrix density of 0.25 grams per cubic centimeter (g/cm³) to 0.55 g/cm³.

9. The apparatus of claim 7, wherein the pad has a latent heat capacity of greater than 100 Joules/gram (J/g).

10. The apparatus of claim 7, wherein the phase change material is a fatty acid.

11. The apparatus of claim 6, wherein the heat sink comprises a composite of an expanded graphite infiltrated phase change material and is positioned laterally adjacent to the integrated circuit device.

12. A method comprising:
thermally coupling a structure comprising an expanded graphite matrix to an integrated circuit package.

13. The method of claim 12, wherein the expanded graphite is infiltrated with a phase change material.

14. The method of claim 13, wherein the structure has a thermal conductivity greater than 5 watts per meter Kelvin (W/mK).

15. The method of claim 13, wherein the structure has a graphite matrix density of 0.075 to 1.500 grams per cubic centimeter (g/cm³), more preferred of 0.25 grams per cubic centimeter (g/cm³) to 0.55 g/cm³.

16. The method of claim 13, wherein the structure has a latent heat capacity of greater than 100 J/g.

17. The method of claim 13, wherein the phase change material is a fatty acid derivative.

18. The method of claim 12, further comprising coupling a passive heat exchanger to the structure.

19. The method of claim 12, wherein the structure is positioned lateral to the integrated circuit device, the method further comprising placing a heat dissipation device on the integrated circuit package, wherein the heat dissipation device is disposed between the integrated circuit package and the structure.
